(19) United States
(12) Patent Application Publication
(10) Pub. No.: US 2002/0195056 A1
(43) Pub. Date: Dec. 26, 2002

(54) Versatile atomic layer deposition apparatus

(76) Inventors: Gurtej Sandhu, Boise, ID (US); Garo J. Derderian, Boise, ID (US)

Correspondence Address: DICKSTEIN SHAPIRO MORIN & OSHINSKY LLP, 2101 L STREET NW, WASHINGTON, DC, 20037-1526, US

(21) Appl. No.: 09/570,340

(22) Filed: May 12, 2000

(51) Int. Cl. C23C 16/00

(52) U.S. Cl. 118/719

(57) ABSTRACT

An improved ALD apparatus is disclosed as having multiple deposition regions in which individual monolayer species are deposited on a substrate under different processing conditions in each region. Each deposition region is chemically separated from an adjacent deposition region. A loading assembly is programmed to follow pre-defined transfer sequences for moving semiconductor substrates into and out of the respective adjacent deposition regions. According to the number of deposition regions provided, a multitude of substrates could be simultaneously processed and run through the cycle of deposition regions until a desired thickness of deposited solid film is obtained.

### FIELD OF THE INVENTION

The present invention relates to the field of semiconductor integrated circuits and, in particular, to an improved apparatus for forming thin film layers through Atomic Layer Deposition (ALD).

### BACKGROUND OF THE INVENTION

Thin film technology in the semiconductor industry requires thin deposition layers, increased step coverage, large production yields, and high productivity, as well as sophisticated technology and equipment for coating substrates used in the fabrication of various devices. For example, process control and uniform film deposition directly affect packing densities for memories that are available on a single chip or device. Thus, the decreasing dimensions of devices and the increasing density of integration in microelectronics circuits require greater uniformity and process control with respect to layer thickness.

Various methods for depositing thin films of complex compounds, such as metal oxides, ferroelectrics, superconductors, or materials with high dielectric constants, are known in the art. Current technologies include mainly RF sputtering, spin coating processes, and chemical vapor deposition (CVD), with its well-known variation called rapid thermal chemical vapor deposition (RTCVD). These technologies, however, have many disadvantages. For example, for the RF sputtering process, most commercially available target sources present significant quantities of impurities, so that, even before the beginning of the sputtering, there is a significant chance of failure due to the impurities in the target source.

Spin deposition of thin films is a complex process, generally involving two steps. The initial step of spinning a stabilized liquid source on a substrate is usually performed in an open environment, which undesirably allows the liquid to absorb impurities and moisture from the environment. In the second drying step, the evaporation of organic precursors from the liquid leaves damaging pores or holes in the thin film.

Both CVD and RTCVD are flux-dependent processes requiring high and uniform substrate temperatures, and uniformity of the chemical species in the process chamber. As substrate size increases, however, these requirements become more critical, creating a demand for complex chamber design and gas flow techniques to maintain the desired uniformity. CVD processes and subsequent annealing steps, which are required by many thin films, such as ferroelectrics, are usually operated at high reactor temperatures, which tend to damage the thin films and the substrates on which they were deposited. Damage to the thin films includes, for example, formation of pores and large grains, removal of certain critical elements, such as lead, and significant nonstoichiometry.

In addition, the step coverage for CVD and RTCVD continues to pose problems, particularly at the initial stages of deposition. Step coverage is defined as the ability of a system to provide a high degree of thickness and uniformity control over a complex topology for thin films. In the initial stage of CVD, a variety of reactive molecules are simultaneously and non-preferentially adsorbed, forming discrete nucleated regions. These nucleated regions, also called islands, continue to grow laterally and vertically and eventually coalesce to form a thin continuous film. At the initial stage of deposition, such a film is discontinuous.

To remedy these deficiencies, the atomic layer epitaxy (ALE) and atomic layer deposition (ALD) processes have been introduced in the thin film technology. Emerging as a variant of CVD, ALD has been recognized as a superior method for achieving good step coverage and transparency to the substrate size. Also, because ALD is a flux-independent process, ultra-uniform thin deposition layers can be achieved, and at a lower processing temperature than that necessary for the conventional CVD or RTCVD.

The ALD technique proceeds by chemisorption at the deposition surface of the substrate. The ALD process is based on a unique mechanism for film formation, that is the formation of a saturated monolayer of a reactive precursor molecules by chemisorption, in which reactive precursors are alternately pulsed into a deposition chamber. Each injection of a reactive precursor is separated by an inert gas purge. Each injection also provides a new atomic layer on top of the previously deposited layers to form a uniform layer of solid film. This cycle is repeated according to the desired thickness of the film.

This unique ALD mechanism for film formation has several advantages over the other technologies mentioned above. First, because of the flux-independent nature of ALD, the transparency of the substrate size increases along with the simplicity of the reactor. Second, the design of the reactor is simple because the area of deposition is independent of the amount of precursor delivered after the formation of the saturated monolayer. Third, interaction and high reactivity of precursor gases is avoided since chemical species are introduced independently, rather than together, into the reactor chamber. Fourth, ALD allows almost a perfect step coverage over complex topography as a result of surface reaction by chemisorption.

Although these advantages make ALD preferred over other film deposition techniques of the art, there are some problems posed by this unique mechanism of film formation. One of them is the throughput limitations of the associated batch processing. Currently, ALD has not been entirely adapted to commercial mass fabrication, mainly because of the system design and gas delivery. Many of the current ALD systems today employ a batch processing, in which substrates are processed in parallel and at the same time. An inherent disadvantage of batch processing is the cross contamination of the substrates from batch to batch, which further decreases the process control and repeatability, and eventually the yield, reliability and net productivity of the process.

Another disadvantage of the ALD technique is the unavoidable contamination that occurs inside the walls of the reactive chamber as a result of the precursor delivery system. A low-profile compact reactor unit typically employs at least two precursor gases, which are alternately introduced and pumped in the same reactor chamber many times during a cycle. Although, desirably, the precursors should be pumped only over the substrate area of interest, in reality, the precursors coat the walls, as well as the heater of the reactor chamber and system. Thus, precursor contamination occurs unavoidably and, as explained above, may affect net production. This drawback is further augmented by the limitations posed by the temperature of the reactor chamber, temperature which technically must vary constantly, according to the nature of the respective gas precursor and the requirements for chemisorption and reactivity.

Accordingly, there is a need for an improved ALD system, which will permit higher commercial productivity and improved versatility. There is also needed a new and improved ALD system and method that will eliminate the problems posed by current batch processing technology, as well as a method and system that will allow a temperature gradient for the ALD processing.

### SUMMARY OF THE INVENTION

The present invention provides an improved and unique ALD system and method for thin film processing. The present invention contemplates an apparatus provided with multiple deposition regions in which individual monolayer species are deposited on a wafer. Each region is chemically isolated from the other deposition regions, for example, by an inert gas curtain. A robot is programmed to follow pre-defined transfer sequences to move wafers into and out of the respective deposition regions for processing. Since multiple regions are provided, a multitude of wafers can be simultaneously processed in respective regions, each region depositing only one monologue species, and each wafer moved through the cycle of regions until a desired film composition and/or thickness is reached.

The present invention allows for the ALD treatment of wafers with higher commercial productivity and improved versatility. Since each region may be provided with a pre-determined set of processing conditions tailored to one particular monolayer species, cross-contamination is greatly reduced.

The foregoing and other advantages and features of the invention will be better understood from the following detailed description of exemplary embodiments of the invention, which is provided in connection with the accompanying drawings.

### DETAILED DESCRIPTION OF THE DRAWINGS

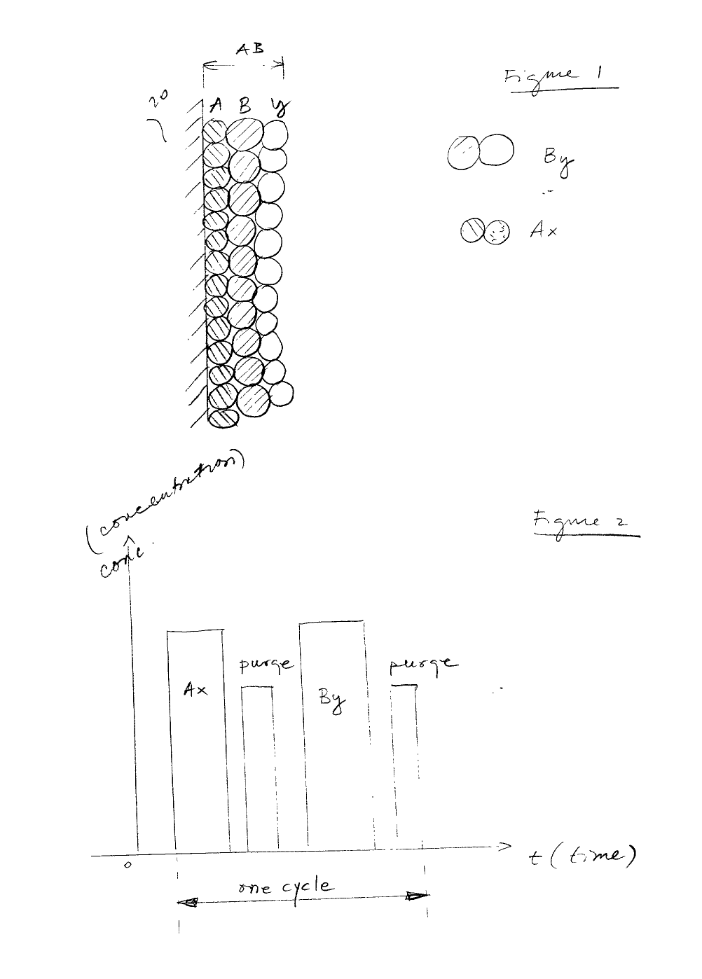

FIG. 1 is a schematic illustration of a conventional atomic layer deposition process.

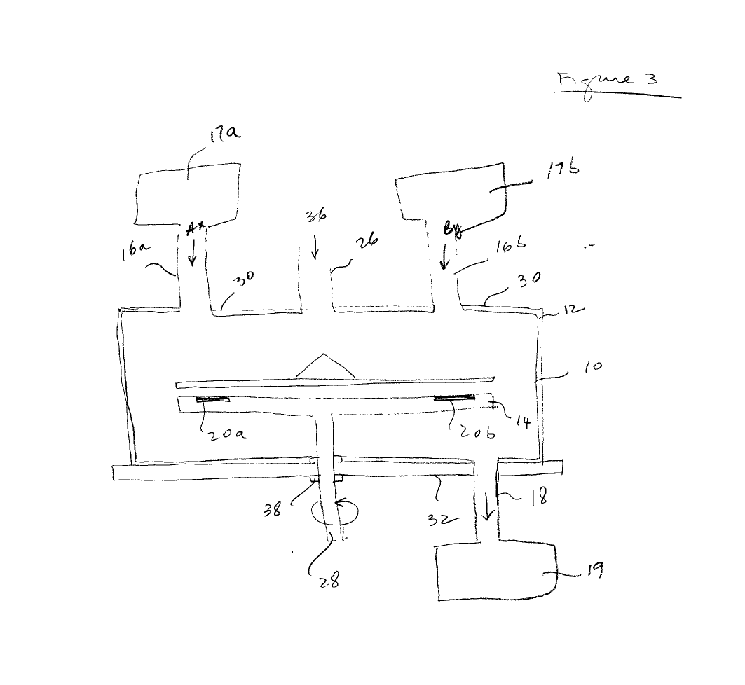

FIG. 2 is a conventional time diagram for atomic layer deposition gas pulsing.

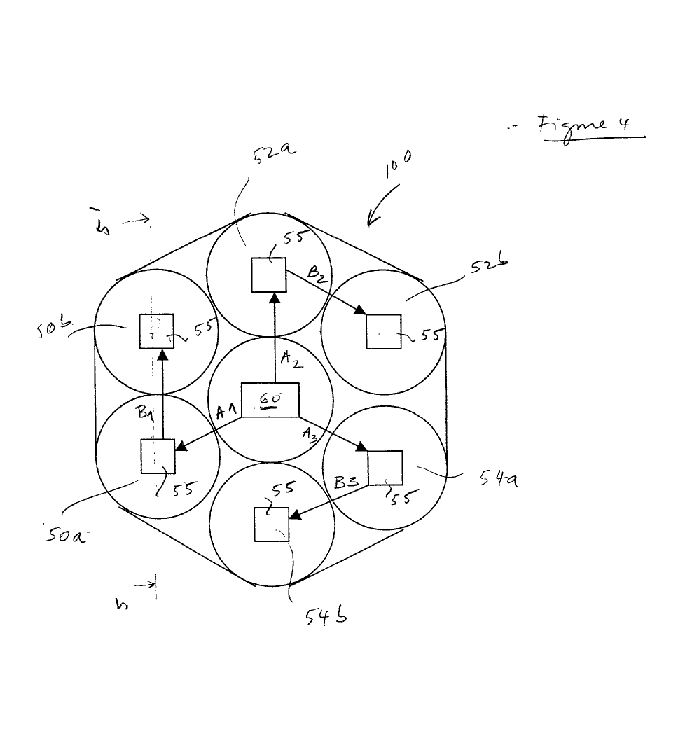

FIG. 3 is an elevation view of a compact reactor unit according to an embodiment of the prior art.

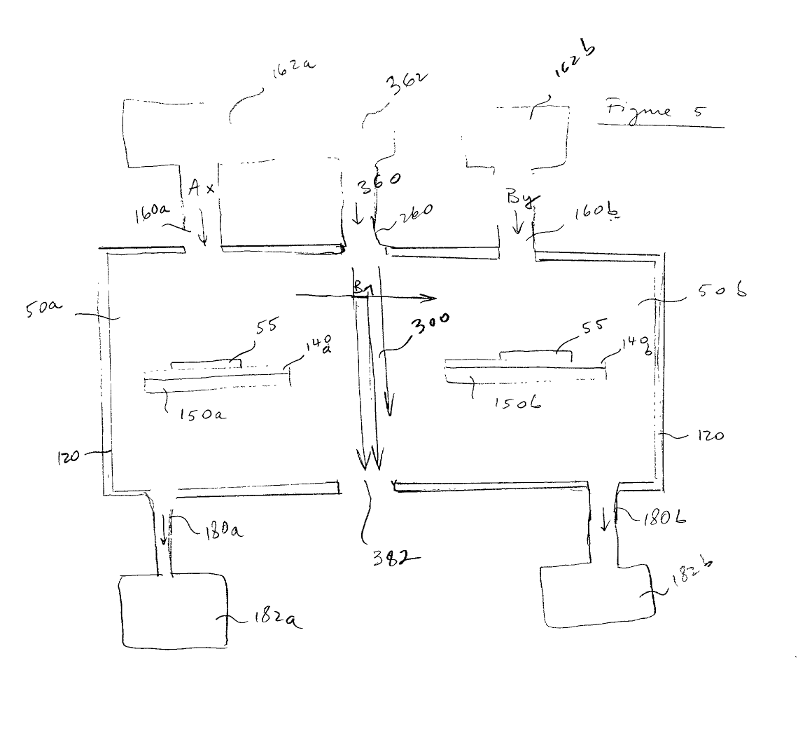

FIG. 4 is a schematic top view of a multiple-chamber atomic layer deposition (ALD) apparatus according to the present invention.

FIG. 5 is a partial cross-sectional of the ALD apparatus of FIG. 4, taken along line 5-5′, and depicting two adjacent deposition regions according to a first embodiment of the present invention and depicting one wafer transfer sequence.

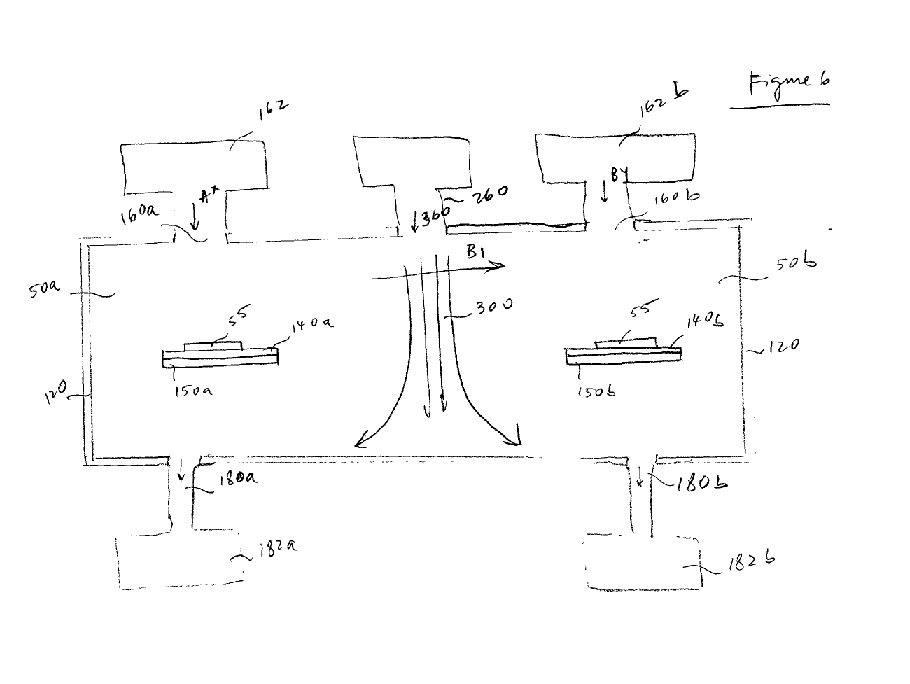

FIG. 6 is a partial cross-sectional of the ALD apparatus of FIG. 4, taken along line 5-5′, and depicting two adjacent deposition regions according to a second embodiment of the present invention.

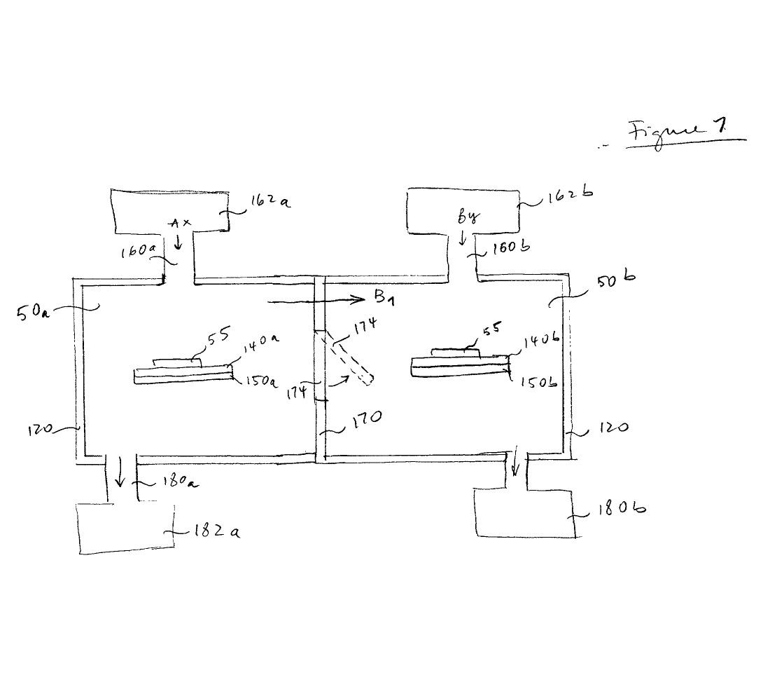

FIG. 7 is a partial cross-sectional view of the ALD apparatus of FIG. 5, depicting a physical barrier between two adjacent deposition chambers.

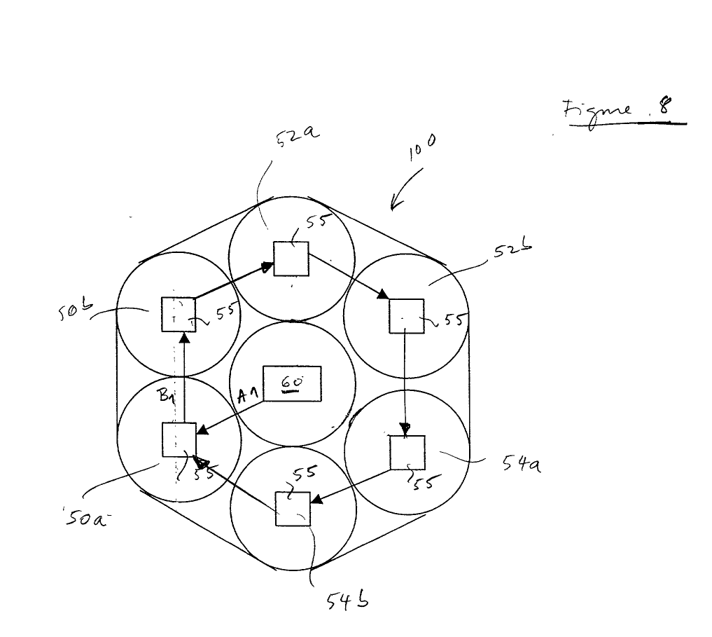

FIG. 8 is a schematic top view of a multiple-chamber atomic layer deposition (ALD) apparatus according to the present invention and depicting a second wafer transfer sequence.

### DETAILED DESCRIPTION OF THE PREFERRED EMBODIMENTS

In the following detailed description, reference is made to various specific embodiments in which the invention may be practiced. These embodiments are described with sufficient detail to enable those skilled in the art to practice the invention, and it is to be understood that other embodiments may be employed, and that various structural, logical, and electrical changes may be made without departing from the spirit or scope of the invention.

The term “substrate” or “wafer” used in the following description may include any semiconductor-based structure that has an exposed silicon surface. Structure must be understood to include silicon-on insulator (SOI), silicon-on sapphire (SOS), doped and undoped semiconductors, epitaxial layers of silicon supported by a base semiconductor foundation, and other semiconductor structures. The semiconductor need not be silicon-based. The semiconductor could be silicon-germanium, germanium, or gallium arsenide. When reference is made to a substrate or wafer in the following description, previous process steps may have been utilized to form regions or junctions in or over the base semiconductor or foundation.

The present invention provides an ALD processing method and apparatus. As it will be described in more detail below, the apparatus is provided with multiple deposition regions in which individual monolayer species are deposited on a substrate under different processing conditions. Each deposition region is chemically separated from the adjacent deposition regions. A robot is programmed to follow pre-defined transfer sequences for moving wafers into and out of the respective adjacent deposition regions. According to the number of deposition regions provided, a multitude of substrates could be simultaneously processed and run through the cycle of different regions until a desired ALD processing of a wafer is completed.

To illustrate the general concepts of ALD, which will be further used in describing the method and apparatus of the present invention, reference is now made to the drawings, where like elements are designated by like reference numerals. FIG. 1 depicts a cross-sectional view of a substrate surface at an initial stage in an ALD process for the formation of a film of materials A and B, which for simplicity may be considered elemental materials. Films that may be formed through the process described above are, for example, ZnS, Al₂O₃, Ta₂O₅, Si₂N₃, SiO₂, TiO₂, SiC, ZnO₂, SrF₂, GaAs, InO₃, and AlN, among others.

As illustrated in FIG. 1, the substrate 20 is exposed to a first species Ax which is deposited over the initial surface of the substrate as a first monolayer. A second species By is next applied over the Ax monolayer. The By species reacts with Ax to form compound AB with y ligand surface bonded on B-atoms (FIG. 1). The Ax, By layers are provided on the substrate surface by first pulsing the first species (also called first precursor gas) Ax and then the second species (also called second precursor gas) By into the region of the surface. If thicker material layers are desired, the sequence of depositing Ax and By layers can be repeated as often as needed until a desired thickness is reached. Between each of the precursor gas pulses, the process region is exhausted and a pulse of purge gas is injected.

FIG. 2 illustrates one complete cycle in the formation of an AB solid material by atomic layer deposition. Initially, a first pulse of precursor Ax is generated followed by a transition time of no gas input. Subsequently, an intermediate pulse of a purge gas takes place, followed by another transition time. Precursor gas By is then pulsed, another transition time follows, and then a purge gas is pulsed again. Thus, a full complete cycle incorporates one pulse of precursor Ax and one pulse of precursor By, each precursor pulse being separated by a purge gas pulse. The first gas pulse Ax results in a layer of A and a ligand x. After the purge gas and the pulsing of second gas precursor By, the y ligand reacts with the x ligand, releasing xy and leaving a surface of y, as shown in FIG. 1. This process is repeated cycle after cycle to acquire the desired thickness on the substrate surface.

The cycle described above for the formation of an AB solid material by atomic layer deposition, is employed in a conventional deposition apparatus, such as the one illustrated in FIG. 3. Such an apparatus includes a reactor chamber 10, which may be constructed as a quartz container, a suscepter 14 which holds one or a plurality of semiconductor substrates, for example, 20a and 20b. Mounted on one of the chamber defining walls, for example on upper wall 30 of the reactor chamber 10, are reactive gas supply inlets 16a and 16b, which are further connected with reactive gas supply sources 17a, 17b supplying first and second gas precursors Ax and By, respectively. An exhaust outlet 18, connected with an exhaust system 19, is situated on an opposite lower wall 32 of the reactor chamber 10. A purge gas inlet 26, connected to a purge gas system, is also provided on the upper wall 30 and in between the reactive gas supply inlets 16a and 16b.

As also shown in FIG. 3, the suscepter 14 is mounted on the upper end of a shaft 28, which is hermetically mounted through the quartz container 12 via a turning mechanism 38. The semiconductor substrates, for example, 20a and 20b, are positioned on top of the suscepter 14, which is then rotated by the shaft 28. When the first reactive gas precursor Ax is supplied into the reactor chamber 10 through the reactive gas inlet 16a, the first reactive gas precursor Ax flows at a right angle to the semiconductor 20a and reacts with its surface portion, in a way similar to that described above with respect to FIG. 1 for the ALD process, to form a thin first monolayer 21a of the first species Ax. After any of the remaining unreacted species Ax is completely exhausted through the exhaust inlet 18, a purge gas 36 is then introduced into the reactor chamber 10 through the inlet 26.

The suscepter 14 is then rotated through the turning mechanism 38 so that the substrate 20a, with the deposited first monolayer 21a, could be exposed to the second reactive gas precursor By, which also flows at a right angle onto the semiconductor 20a and the first monolayer 21a, to form a deposited second monolayer 21b over the first monolayer 21a. Any remaining reactive precursors in the reactive chamber 10 are exhausted through the exhaust inlet 18. As explained above, this cycle could be repeated for a number of times, according to the desired thickness of the deposited film. Of course, the same exact processing steps apply to substrate 20b. Also, as known in the art, reactor walls may be heated by infrared lamps or radio frequency energy to raise the temperature inside the reactor chamber 10, since higher temperatures may lead to less chemisorption and depositions on the reactor walls.

While systems based on rotating substrate holders, such as the one described above with reference to FIG. 3, have a high sequencing speed and easy application to different types of reactants, including those necessitating high-temperature sources, a major disadvantage is a small flexibility to achieve the complex sequences needed in superlattices or multilayer structures. Further, as described above, although the gas precursors Ax and By should flow only over the substrate area of interest, that is substrates 20a and 20b at different stages of deposition processing, in reality, the precursors undesirably coat the walls, as well as any heater system of the reactor chamber 10. Thus, precursor contamination occurs unavoidably and the net production is ultimately affected.

The present invention overcomes the above mentioned disadvantages by providing instead a simple and novel multi-chamber system for ALD processing. Although the present invention will be described below with reference to the atomic layer deposition of an AB solid material using Ax and By species, it must be understood that the present invention has equal applicability for the formation of any film of any material capable of being formed by ALD deposition techniques using any number of species, where each species is deposited in a reaction chamber dedicated thereto.

A schematic top view of a multiple-chamber ALD apparatus 100 of the present invention is shown in FIG. 4. According to a preferred embodiment of the present invention, deposition regions 50a, 50b, 52a, 52b, 54a, and 54b are alternately positioned around a loading mechanism 60, for example a robot. These deposition regions may be any regions for the ALD treatment of substrates. The deposition regions may be formed as cylindrical reactor chambers, 50a, 50b, 52a, 52b, 54a, and 54b, in which adjacent chambers are chemically isolated from one another. To facilitate wafer movement, and assuming that only two monolayer species Ax, By are to be deposited, the reactor chambers are arranged in pairs 50a, 50b; 52a, 52b; 54a, 54b. One such pair, 50a, 50b is shown in FIG. 5. Each of the reactor chambers of a pair deposits one of the monolayer species Ax, By. The adjacent reactor chamber pairs are chemically isolated from one another, for example by a gas curtain, which keeps the monolayer species Ax, By in a respective region, and which allows wafers treated in one reaction chamber, for example 50a, to be easily transported by the robot 60 to the other reaction chamber 50b, and vice versa. Simultaneously, the robot can also move wafers between chambers 52a or 52b, and 54a and 54b.

In order to chemically isolate the paired reaction chambers 50a, 50b; 52a, 52b; and 54a, 54b, the paired reaction chambers show a wall through which the wafers may pass, with the gas curtain acting in effect as a chemical barrier preventing the gas mixture within one chamber, for example 50a, from entering the paired adjacent chamber, for example 50b.

It should be noted that, when alternating sequences of monolayer species deposition is required, the robot can simply move wafers back and forth between the adjacent chambers, for example 50a, 50b, until a desired layer thickness on the wafer is obtained.

It should also be noted that, while two adjacent chambers have been illustrated for depositing respective monolayer species Ax, By, one or more additional chambers, for example 50c, 52c, 54c, may also be used for deposition of additional respective monolayer species, such as Cz, for example, with the additional chambers being chemically isolated from the chambers depositing the Ax and By monolayer species in the same way the chambers for depositing the Ax and By species are chemically isolated.

The loading assembly 60 of FIG. 4 may include an elevator mechanism along with a wafer supply mechanism. As well-known in the art, the supply mechanism may be further provided with clamps and pivot arms, so that a wafer 55 can be maneuvered by the robot and positioned according to the requirements of the ALD processing described in more detail below.

Further referring to FIG. 4, a processing cycle for atomic layer deposition on a wafer 55 begins by selectively moving a first wafer 55, from the loading assembly 60 to the chamber reactor 50a, in the direction of arrow A₁ (FIG. 4). Similarly, a second wafer 55′ may be selectively moved by the loading assembly 60 to the chamber reactor 52a, in the direction of arrow A₂. Further, a third wafer 55″ is also selectively moved by the loading assembly 60 to the chamber reactor 54a, in the direction A₃. At this point, each of chambers 50a, 52a, 54a are ready for deposition of a first monolayer species, for example Ax, which now occurs.

FIG. 5 illustrates a cross-sectional view of the apparatus 100 of FIG. 4, taken along line 5-5′. For simplicity, FIG. 5 shows only a cross-sectional view of adjacent reactor chambers 50a and 50b. In order to deposit an atomic monolayer on the wafer 55, the wafer 55 is placed inside of the reactor chamber 50a, which may be provided as a quartz or aluminum container 120. The wafer 55 is placed by the loading assembly 60 (FIG. 4) onto a suscepter 140a (FIG. 5), which in turn is situated on a heater assembly 150a. Mounted on the upper wall of the reactor chamber 50a is a reactive gas supply inlet 160a, which is further connected to a reactive gas supply source 162a for a first gas precursor Ax. An exhaust outlet 180a, connected to an exhaust system 182a, is situated on the opposite wall from the reactive gas supply inlet 160a.

The wafer 55 is positioned on top of the suscepter 140a by the loading assembly 60, and then the reactive gas precursor Ax is supplied into the reactor chamber 50a through the reactive gas inlet 160a. The precursor Ax flows at a right angle onto the wafer 55 and reacts with its top substrate surface to form a first monolayer 210a of the first species Ax. The ALD mechanism for the formation of the first monolayer 210a of the first gas species Ax was described above with reference to FIGS. 1 and 2 and it will not be described here again.

After the deposition of a monolayer of a first precursor gas on the wafer surface 55, the processing cycle for the wafer 55 continues with the removal of the wafer 55 from the chamber reactor 50a to the chamber reactor 50b, in the direction of arrow B₁, as also illustrated in FIG. 4. After the deposition of the first monolayer 210a of the first species Ax, the wafer 55 is moved from the reactor chamber 50a , through a gas curtain 300 (FIG. 5), to the reactor chamber 50b, by the loading assembly 60 (FIG. 4) and in the direction of arrow B₁ of FIG. 5. It is important to note that the gas curtain 300 provides chemical isolation between adjacent deposition regions.

The loading assembly 60 moves the wafer 55 through the gas curtain 300, onto the suscepter 140b situated in the reactor chamber 50b. A heater assembly 150b is positioned under the suscepter 140b. A reactive gas supply inlet 160b, which is further connected to a reactive gas supply source 162b, for a second gas precursor By, is mounted on the upper wall of the reactor chamber 50b. An exhaust inlet 180b, connected to an exhaust system 182b, is further situated on the opposite wall to the reactive gas supply inlet 160b.

Next, the reactive gas precursor By is supplied into the reactor chamber 50b through the reactive gas inlet 160b, the precursor By flows at a right angle onto the deposited first monolayer 210a of the first species Ax. This way, reactive gas precursor By reacts with the top surface of the first monolayer 210a to form a second monolayer 210b of the second species By. The ALD mechanism for the formation of the first and second monolayers 210a and 210b of the two gas species Ax and By was described in detail with reference to FIGS. 1 and 2.

Following the deposition of the second monolayer 210b of the second species By, the process continues with the removal of the wafer 55 from the reactor chamber 50b, through the gas curtain 300, and into the reactor chamber 50a to continue the deposition process. This process is repeated cycle after cycle, with the wafer 55 traveling back and forth between the reactor chamber 50a, and the reactor chamber 50b, to acquire the desired thickness of the AB film. As known in the industry, examples of AB films deposited by employing the ALD apparatus 100 (FIGS. 4 and 5) of the present invention are ZnS, Al₂O₃, Ta₂O₅, Si₂N₃, SiO₂, TiO₂, SiC, ZnO₂, SrF₂, GaAs, InO₃, AlN, GAN, SrSCe, and ZnF₂, among others. Thus, very thin films, such as gate oxides, cells dielectrics, and diffusion barriers, are formed with various dimensions at specified characteristics.

By employing chemically separate reactor chambers for the deposition process of each species, e.g., Ax, By and possibly others, the present invention has the major advantage of allowing different processing conditions, for example, deposition temperatures, in different reactor chambers. This is important since the chemisorption and reactivity requirements of the ALD process have specific temperature requirements, in accordance with the nature of the precursor gas. Accordingly, the apparatus of the present invention allows, for example, reactor chamber 50a to be set to a different temperature than that of the reactor chamber 50b. Further, each reactor chamber may be optimized either for improved chemisorption or for improved reactivity.

The configuration of the ALD apparatus illustrated above also improves the overall yield and productivity of the deposition process, since each chamber could run a separate substrate, and therefore, a plurality of substrates could be run simultaneously at a given time. In addition, since each reactor chamber accommodates only one gas precursor, cross-contamination from one wafer to another is greatly reduced. Moreover, the production time can be decreased since the configuration of the apparatus of the present invention saves a great amount of purging and reactor clearing time.

Of course, although the deposition process was explained above only with reference to the first substrate 55 in the first chamber reactor 50a and the second chamber reactor 50b, it is to be understood that same processing steps are carried out simultaneously on the second and third wafers 55′, 55″ for their respective chamber reactors. Further, the second and third wafers 55′, 55″ are moved accordingly, in the directions of arrows A₂, B₂ (corresponding to chamber reactors 52a, 52b) and arrows A₃, B₃ (corresponding to chamber reactors 54a, 54b). Moreover, while the deposition process was explained above with reference to only one first substrate 55 for the first and second reactor chambers 50a, 50b, it must be understood that the first and second reactor chambers 50a, 50b could also process another first substrate 55, in a direction opposite to that of processing the other first substrate. For example, if one first substrate 55 travels in the direction of arrow B₁ (FIG. 4) the other first substrate 55 could travel in the opposite direction of arrow B₁, that is from the second reactor chamber 50b to the first reactor chamber 50a.

Assuming a thick layer of material is to be deposited on the wafers 55, after the deposition of the monolayer of the second precursor gas on the wafer 55 in the reactor chamber 50b, the wafer 55 is then moved back by the assembly system 60 to the reactor chamber 50a, where a second monolayer of the first precursor gas is next deposited over the first monolayer of the second precursor gas. The wafer 55 is further moved to the reactor chamber 50b for the subsequent deposition of a second monolayer of the second precursor gas. The cycle continues until a desired thickness of the solid film on the surface of the wafer 55 is achieved, and, thus, the wafer 55 travels back and forth between reactor chambers 50a and 50b. As explained above, the same cycle process applies to the other two wafers that are processed simultaneously in their respective reactor chambers.

Although the invention is described with reference to reactor chambers, any other type of deposition regions may be employed, as long as the wafer 55 is positioned under a flow of gas precursor. The gas curtain 300 provides chemical isolation to all adjacent deposition regions. Thus, as illustrated in FIGS. 5-6, the gas curtain 300 is provided between the two adjacent reactor chambers 50a and 50b so that an inert gas 360, such as nitrogen, argon, or helium, for example, flows through an inlet 260 connected to an inert gas supply source 362 to form the gas curtain 300, which keeps the gas species Ax and By from flowing into an adjacent reaction chamber. An exhaust outlet 382 (FIG. 5) is further situated on the opposite wall to the inert gas inlet 260. It must also be noted that the pressure of the inert gas 360 must be higher than that of the first precursor gas Ax and that of the second precursor gas By, so that the two precursor gases are constrained by the gas curtain 300 to remain within their respective reaction chambers.

FIG. 6 illustrates a cross-sectional view of the apparatus 100 of FIG. 5, with same adjacent reactor chambers 50a and 50b, but in which the inert gas 360 shares the exhaust outlets 180a and 180b with the two gas precursors Ax and By, respectively. Thus, the ALD apparatus 100 may be designed so that the inert gas 360 of the gas curtain 300 could be exhausted through either one or both of the two exhaust outlets 180a and 180b, instead of being exhausted through its own exhaust outlet 382, as illustrated in FIG. 55.

FIG. 7 shows another alternate embodiment of the apparatus in which the gas curtain 300 separating adjacent chambers in FIGS. 5-6 is replaced by a physical boundary, such as a wall 170 having a closeable opening 172. A door 174 (FIG. 7) can be used to open and close the opening 172 between the adjacent paired chambers 50a, 50b. This way, the wafer 55 can be passed between the adjacent chambers 50a, 50b through the open opening 172 by the robot 60, with the door 174 closing the opening 172 during ALD deposition.

Although the present invention has been described with reference to only three semiconductor substrates processed at relatively the same time in respective pairs of reaction chambers, it must be understood that the present invention contemplates the processing of any “n” number of wafers in their corresponding “m” number of reactor chambers, where n and m are integers. Thus, in the example shown in FIG. 4, n=3 and m=6, providing an ALD apparatus with at least 6 reaction chambers that could process simultaneously 3 wafers for a repeating two-step ALD deposition of Ax and By. It is also possible to have n=2 and m=6 where two wafers are sequentially transported to and processed in the reaction chambers for sequential deposition of species Ax, By, and Cz. Other combinations are also possible. Thus, although the invention has been described with the wafer 55 traveling back and forth from the reactor chamber 50a to the reactor chamber 50b with reference to FIG. 7, it must be understood that, when more than two reactor chambers are used to deposit more than two monolayer species Ax, By, the wafer 55 will be transported by the loading assembly 60 among all the reaction chambers in a sequence required to produce a desired ALD layering.

Also, although the present invention has been described with reference to wafers 55, 55′ and 55″ being selectively moved by the loading assembly 60 to their respective reactor chambers 50a and 50b (for wafer 55), 52a and 52b (for wafer 55′), and 54a and 54b (for wafer 55″), it must be understood that each of the three above wafers or more wafers could be sequentially transported to, and processed in, all the reaction chambers of the apparatus 100. This way, each wafer could be rotated and moved in one direction only. Such a configuration is illustrated in FIG. 8, according to which a processing cycle for atomic layer deposition on a plurality of wafers 55, for example, begins by selectively moving each wafer 55, from the loading assembly 60 to the chamber reactor 50a, in the direction of arrow A₁ (FIG. 8), and then further to the reactor chamber 50b, 52a, 52b, 54a, and 54b. One reaction chamber, for example 50a, can serve as the initial chamber and another, for example 54b, as the final chamber. Each wafer 55 is simultaneously processed in a respective chamber and is moved sequentially through the chambers by the loading assembly 60, with the cycle continuing with wafers 55 traveling in one direction to all the remaining reactors chambers. Although this embodiment has been described with reference to a respective wafer in each chamber, it must be understood that the present invention contemplates the processing of any “n” number of wafers in their corresponding “m” number of reactor chambers, where n and m are integers and n≦m. Thus, in the example shown in FIG. 8, the ALD apparatus with 6 reaction chambers could process simultaneously up to 6 wafers.

The above description illustrates preferred embodiments that achieve the features and advantages of the present invention. It is not intended that the present invention be limited to the illustrated embodiments. Modifications and substitutions to specific process conditions and structures can be made without departing from the spirit and scope of the present invention. Accordingly, the invention is not to be considered as being limited by the foregoing description and drawings, but is only limited by the scope of the appended claims. What is claimed as new and desired to be protected by Letters Patent of the United States is:

1. An atomic layer deposition apparatus comprising:
a first atomic layer deposition region for depositing a first gas species on a first substrate as a monolayer;
a second atomic layer deposition region for depositing a second gas species on said first substrate as a monolayer, said first and second deposition regions being chemically isolated from one another; and
a loading assembly for moving said first substrate from said first deposition region to said second deposition region, thereby enabling deposition of a first atomic monolayer in said first deposition region, followed by deposition of a second atomic monolayer in said second deposition region.

2. The deposition apparatus of claim 1, wherein said first and second deposition regions are adjacent to one another and chemically isolated.

3. The deposition apparatus of claim 2, wherein said first and second deposition regions are chemically isolated from one another by a gas curtain.

4. The deposition apparatus of claim 3, wherein said gas curtain is formed of an inert gas.

5. The deposition apparatus of claim 2, wherein said first and second deposition regions are chemically isolated from one another by a physical barrier having a closeable opening through which said loading assembly can move a substrate.

6. The deposition apparatus of claim 1, wherein said loading assembly is further able to move said substrate from said second deposition region back to said first deposition region.

7. The deposition apparatus of claim 1 further comprising a plurality of first and second atomic layer deposition regions.

8. The deposition apparatus of claim 7, wherein said plurality of first and second deposition regions are grouped in pairs of first and second deposition regions, so that at least said first substrate and a second substrate can be treated simultaneously in respective pairs of first and second deposition regions.

9. The deposition apparatus of claim 8 further comprising a third pair of first and second atomic layer deposition regions for processing a third substrate in said third pair of first and second atomic layer deposition regions simultaneously with processing of said first and second substrates.

10. The deposition apparatus of claim 7, wherein said loading assembly is located at the center of said deposition regions.

11. The deposition apparatus of claim 1 further comprising at least one third atomic layer deposition region.

12. The deposition apparatus of claim 11, wherein said first, second, and third deposition regions are adjacent to one another and chemically isolated.

13. The deposition apparatus of claim 12, wherein said first, second, and third deposition regions are chemically isolated from one another by a gas curtain.

14. The deposition apparatus of claim 13, wherein said gas curtain is formed of an inert gas.

15. The deposition apparatus of claim 13, wherein said first, second, and third deposition regions are chemically isolated from one another by a physical barrier having a closeable opening through which said loading assembly can move a substrate.

16. The deposition apparatus of claim 11, wherein said loading assembly is further able to move sequentially said first substrate among said first deposition region, said second deposition region, and said third deposition region.

17. The deposition apparatus of claim 16, wherein said loading assembly is further able to move sequentially another substrate among said first deposition region, said second deposition region, and said third deposition region.

18. An atomic layer deposition apparatus comprising:
a plurality of atomic layer deposition regions, each for depositing a respective gas species on a first substrate as a monolayer, each of said plurality of regions being chemically isolated from one another; and
a loading assembly for moving said first substrate through at least two of said plurality of atomic layer deposition regions in accordance with a first predefined pattern.

19. The deposition apparatus of claim 18, wherein said loading assembly is further able to move said substrate through all of said plurality of atomic layer deposition regions.

20. The deposition apparatus of claim 18, wherein said loading assembly is further able to move said substrate through predetermined regions of said plurality of atomic layer deposition regions.

21. The deposition apparatus of claim 20, wherein said loading assembly moves said substrate between two adjacent atomic layer deposition regions.

22. The deposition apparatus of claim 20, wherein said loading assembly moves said substrate among three adjacent atomic layer deposition regions.

23. The deposition apparatus of claim 18, wherein said loading assembly is further able to move a second substrate through at least two of said plurality of atomic layer deposition regions in accordance with a second predefined pattern.

24. The deposition apparatus of claim 18, wherein said loading assembly is further able to move a plurality of substrates, each of said plurality of substrates residing in respective regions, to another of said plurality of regions.

25. The deposition apparatus of claim 24, wherein said loading assembly is further able to move sequentially said plurality of substrates through all said deposition regions.

26. The deposition apparatus of claim 24, wherein said loading assembly is further able to move said plurality of substrates through predetermined regions of said deposition regions.

27. The deposition apparatus of claim 18, wherein said loading assembly is located at the center of said deposition regions.

28. The deposition apparatus of claim 18, wherein said deposition regions are adjacent to one another and chemically isolated.

29. The deposition apparatus of claim 28, wherein said deposition regions are chemically isolated from one another by a gas curtain.

30. The deposition apparatus of claim 29, wherein said gas curtain is formed of an inert gas.

31. The deposition apparatus of claim 28, wherein said deposition regions are chemically isolated from one another by a physical barrier having a closeable opening through which said loading assembly can move a substrate.

32. A method of operating an atomic layer deposition apparatus, said deposition apparatus comprising a first deposition region and a second deposition region, said first and second deposition regions being chemically isolated from one another, said method comprising the steps of:
positioning a wafer in said first deposition region;
introducing a first gas species into said first deposition region and depositing said first gas species on said wafer as a first atomic monolayer;
moving said wafer from said first deposition region to said second deposition region; and
introducing a second gas species into said second deposition region and depositing said second gas species on said wafer as a second atomic monolayer.

33. The method of claim 32 further comprising the step of moving said wafer back and forth between said first and second deposition regions and depositing a respective gas species in each of said deposition regions.

34. The method of claim 32, wherein said first and second deposition regions are adjacent to each other.

35. The method of claim 32 further comprising the step of simultaneously processing at least two wafers among said first and second deposition regions and depositing a respective gas species in each of said deposition regions.

36. The method of claim 32, wherein said least two wafers are sequentially moved among said first and second deposition regions.

37. A method of conducting atomic layer deposition comprising the steps of:
depositing a first monolayer species on a substrate in a first deposition region;
moving said substrate from said first deposition region to a second deposition region, which is chemically isolated from said first deposition region; and
depositing a second monolayer species on said substrate in said second deposition region.

38. The method of claim 37, wherein said step of depositing said first monolayer species further comprises introducing a first gas species into said first deposition region.

39. The method of claim 37, wherein said step of depositing said second monolayer species further comprises introducing a second gas species into said second deposition region.

40. The method of claim 37 further comprising the step of moving said substrate back and forth between said first and second deposition regions and depositing a respective gas species in each of said deposition regions.

41. The method of claim 37 wherein a plurality of first and second deposition regions are provided, and said method further comprising depositing said first and second monolayer species on respective substrates in respective pairs of first and second deposition regions, said first and second deposition regions of each pair being adjacent to one another.

42. The method of claim 41, wherein a plurality of substrates, each of said plurality of substrates residing in respective regions, are moved sequentially from said first deposition regions to said second deposition regions.

43. The method of claim 40 further comprising the step of moving said substrate from said first deposition region, to said second deposition region, and to a third deposition region.

44. The method of claim 43 further comprising the step of processing simultaneously at least two substrates, each of said two substrates residing in respective regions, among all said first, second, and third deposition regions.

45. The method of claim 43, wherein said least two substrates, each of said two substrates residing in respective regions, are moved sequentially to said first deposition region, to said second deposition region, and to said third deposition region.

46. A method of operating an atomic layer deposition apparatus, said deposition apparatus comprising a plurality of deposition regions, said deposition regions being chemically isolated from one another, said method comprising the steps of:
positioning a plurality of wafers in respective deposition regions;
introducing a first gas species into some of said plurality of deposition regions and depositing said first gas species on at least one of said plurality of wafers as a first atomic monolayer;
moving said plurality of wafers from said some of said plurality of deposition regions to other deposition regions; and
introducing a second gas species into said other deposition regions and depositing said second gas species on at least one of said plurality of wafers as a second atomic monolayer.

47. The method of claim 46 further comprising the step of sequentially moving said plurality of wafers through at least two of said plurality of deposition regions in accordance with a predefined pattern.

48. The method of claim 46 further comprising the step of sequentially moving said plurality of wafers through all said deposition regions.

49. The method of claim 46 further comprising the step of sequentially moving said plurality of wafers through predetermined regions of said deposition regions.
